(19) United States
(12) Patent Application Publication
(10) Pub. No.: US 2018/0158808 A1
(43) Pub. Date: Jun. 7, 2018

(54) LED DISPLAY MODULE, DISPLAY DEVICE AND METHOD OF MANUFACTURING LED DISPLAY MODULE

(71) Applicant: BOE TECHNOLOGY GROUP CO., LTD., Beijing (CN)

(72) Inventors: Yu Zhang, Beijing (CN); Yushi Liu, Beijing (CN)

(21) Appl. No.: 15/576,278

(22) PCT Filed: Apr. 18, 2017
(86) PCT No.: PCT/CN2017/080890

§ 371 Date: Nov. 21, 2017

(30) Foreign Application Priority Data
Apr. 25, 2016 (CN) 201610262716.8

(51) Int. Cl. H01L 25/16; H01L 33/50; H01L 25/075; H01L 33/40; H01L 33/32; H01L 33/62

(52) U.S. Cl. CPC H01L 25/167; H01L 33/507; H01L 25/0753; H01L 27/124; H01L 33/32; H01L 33/62; H01L 33/405

(57) ABSTRACT

Elements of the present disclosure provide a LED display module, a display device and a method of manufacturing a display module, and belongs to the field of display device. A LED display module includes: a substrate, a plurality of inorganic LED chips, control circuits, a photoluminescent layer and a transparent cover plate. The transparent cover plate and the substrate are provided opposite to each other, the control circuits, the photoluminescent layer and the plurality of inorganic LED chips are between the transparent cover plate and the substrate, the plurality of inorganic LED chips are arranged in array on one side face of the substrate and the plurality of inorganic LED chips are connected respectively to the control circuits such that the control circuits drive the plurality of inorganic LED chips to emit light; the photoluminescent layer is between the transparent cover plate and the plurality of inorganic LED chips such that the photoluminescent layer excites colored light under irradiation of the light emitted by the inorganic LED chips. With provision of the photoluminescent layer on the inorganic LED chips, the photoluminescent layer excites colored light under irradiation of the light emitted by the inorganic LED chips.

### CROSS-REFERENCE TO RELATED APPLICATION

This application claims priority to Chinese Patent Application No. 201610262716.8, which is titled as “LED display module, display device and method of manufacturing display module”, filed on Apr. 25, 2016 in the State Intellectual Property Office of China, the present disclosure of which is hereby incorporated by reference in its entirety.

### TECHNICAL FIELD

Embodiments of the present disclosure relate to the field of display device, and particularly, to a LED (light emitting diode) display module, a display device and a method of manufacturing a LED display module.

### BACKGROUND

Currently, common display devices includes passive light emitting display device (such as liquid crystal display device) and active light emitting display device (such as organic light emitting diode (OLED) display device). Because no backlight plate is needed to be provided in the active light emitting display device, the active light emitting display device has advantages of smaller in thickness, lower in power consumption, higher in response time compared with the passive light emitting display device, and thus has greater market competitiveness.

OLED display device mainly adopts active matrix/organic light emitting diode (AMOLED) display module. An AMOLED display module mainly includes a transparent substrate, a control circuit provided on the transparent substrate, an OLED connected to the control circuit, and a control chip. The AMOLED display module has its luminescence principle that it can excite different organic semiconductor materials in OLED chip by current so that different colors of light can be obtained.

However, service life of organic materials is not long, especially, service life of an organic material generating blue light is very short (only about 1000 hours), so, the current AMOLED display module has short service life due to being limited to the service life of organic materials, which greatly limits life of the display device. In addition, since the AMOLED has low light effect in generating blue light, in order to increase brightness of the blue light, usually a method of increasing the current and improving power consumption is adopted, which increases power consumption of the AMOLED.

### SUMMARY

Embodiments of the present disclosure provides a light emitting diode display module, a display device and a method of manufacturing a display module, which can prolong service life of the display module and reduce power consumption of the display module. The technical solution is provided as follows.

In one aspect, according to embodiments of the present disclosure, there is provided a LED display module comprising: a substrate, a plurality of inorganic LED chips, control circuits, a photoluminescent layer and a transparent cover plate; wherein, the transparent cover plate and the substrate are provided opposite to each other, the control circuits, the photoluminescent layer and the plurality of inorganic LED chips are between the transparent cover plate and the substrate, the plurality of inorganic LED chips are arranged in array on one side face of the substrate and the plurality of inorganic LED chips are connected respectively to the control circuits such that the control circuits drive the plurality of inorganic LED chips to emit light; the photoluminescent layer is between the transparent cover plate and the plurality of inorganic LED chips such that the photoluminescent layer excites colored light under irradiation of the light emitted by the inorganic LED chips.

Optionally, the photoluminescent layer and the control circuits are formed at the same side face of the transparent cover plate.

Optionally, the control circuit comprise a gate line and a data line crossing the gate line, and a plurality of the gate lines and a plurality of the data lines are crossed with one another to form a plurality of meshes, a pixel driving circuit is provided in each of the meshes and is connected with the gate line and the data line, respectively, and the pixel driving circuits are connected in a one-to-one correspondence with the inorganic LED chips.

Optionally, the photoluminescent layer comprises a plurality of photoluminescent units, each photoluminescent unit corresponding to three of the inorganic LED chips provided side by side along the gate line.

Optionally, the photoluminescent unit comprises a first sub-photoluminescent unit and a second sub-photoluminescent unit provided alternately, the first sub-photoluminescent unit excites a red light under irradiation of the light emitted by the inorganic LED chips, the second sub-photoluminescent unit excites a green light under irradiation of the light emitted by the inorganic LED chips, and the light emitted by the inorganic LED chips is a blue light.

Furthermore, the photoluminescent unit further comprises a third sub-photoluminescent unit, and the third sub-photoluminescent unit excites a blue light under irradiation of the light emitted by the inorganic LED chips.

Optionally, the blue light excited by the third sub-photoluminescent unit under irradiation of the light emitted by the inorganic LED chips has a wavelength of 450 nm˜460 nm.

Optionally, the photoluminescent layer is a quantum dot color filter film.

Optionally, the LED display module further comprises a passivation layer between the control circuits and the inorganic LED chips, the passivation layer is provided with a through hole thereon, and an anode of the inorganic LED chip is connected to the control circuit through a conductor provided in the through hole.

Furthermore, the conductor is made of tin indium oxide.

Optionally, a material for a cathode of the inorganic LED chip comprises a copper-platinum-gold ternary alloy.

Optionally, the inorganic LED chip comprises a N-type gallium nitride layer formed on one side face of the substrate, a heavily doped gallium nitride layer formed on a partial region of the N-type gallium nitride layer, and a P-type gallium nitride layer formed on the heavily doped gallium nitride layer; and, the N-type gallium nitride layer is provided with the cathode and the P-type gallium nitride layer is provided with the anode.

Optionally, the substrate comprises a sapphire substrate.

Optionally, the LED display module further comprises a light reflecting layer provided at one side face of the substrate away from the inorganic LED chips.

In another aspect, according to embodiments of the present disclosure, there is also provided a LED display device, wherein, the display device comprises any one of the LED display modules.

In yet another aspect, according to embodiments of the present disclosure, there is also provided a method of manufacturing a LED display module, and, the method comprises:

providing a substrate;

manufacturing inorganic LED chips, a photoluminescent layer and control circuits on one side face of the substrate, wherein, the plurality of inorganic LED chips are arranged in array on one side face of the substrate and the plurality of inorganic LED chips are connected respectively to the control circuits, the control circuits are configured to drive the plurality of inorganic LED chips to emit light; in a direction perpendicular to the substrate, the photoluminescent layer is located above the inorganic LED chips and is configured to excite colored light under irradiation of the light emitted by the inorganic LED chips;

assembling the substrate with a transparent cover plate.

In still another aspect, according to embodiments of the present disclosure, there is also provided a method of manufacturing a LED display module, wherein, the method comprises:

providing a substrate;

manufacturing a plurality of inorganic LED chips on one side face of the substrate, the plurality of inorganic LED chips being arranged in array on the one side face of the substrate;

manufacturing a photoluminescent layer and control circuits on one side face of a transparent cover plate, wherein, the control circuits are configured to drive the plurality of inorganic LED chips to emit light, and the photoluminescent layer is configured to excite colored light under irradiation of the light emitted by the inorganic LED chips;

assembling the substrate with the transparent cover plate such that the plurality of inorganic LED chips are connected respectively with the control circuits.

### BRIEF DESCRIPTION OF THE DRAWINGS

In order to provide a more clear explanation of technical solutions in embodiments of the present disclosure, there is provided a brief introduction of the attached drawings used in the following description of the embodiments. Obviously, the drawings mentioned in the following description belong to some embodiments of the present disclosure. However, for those skilled in the art, other drawings may be achieved on the basis of these attached drawings without involving any inventive steps.

FIG. 1 is a schematic view showing a structure of a LED display module according to an embodiment of the present disclosure;

FIG. 2 is a schematic view showing a structure of a substrate of the LED display module according to the embodiment of the present disclosure;

FIG. 3 is a schematic view showing a structure of a transparent cover plate of the LED display module according to the embodiment of the present disclosure;

FIG. 4 is a schematic view showing a structure of another LED display module according to an embodiment of the present disclosure;

FIG. 5 is a flow diagram showing a method of manufacturing a LED display module according to an embodiment of the present disclosure; and

FIG. 6 is a flow diagram showing another method of manufacturing a LED display module according to an embodiment of the present disclosure.

### DETAILED DESCRIPTION OF THE EMBODIMENTS

In order to provide a more clear understanding of technique solutions of embodiments of the present disclosure, the embodiments of the present disclosure will be further described hereinafter in detail and completely with reference to the attached drawings.

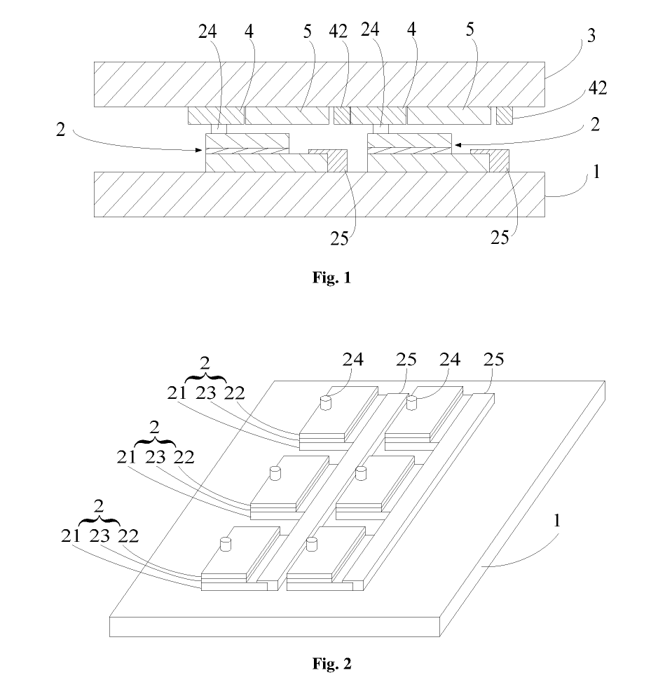

FIG. 1 is a schematic view showing a structure of a LED display module according to an embodiment of the present disclosure. Referring to FIG. 1, the LED display module comprises: a substrate 1, a plurality of inorganic LED chips 2, control circuits 4, a photoluminescent layer 5 and a transparent cover plate 3. The transparent cover plate 3 and the substrate 1 are provided to be opposite to each other, and the control circuits 4, the photoluminescent layer 5 and the plurality of inorganic LED chips 2 are between the transparent cover plate 3 and the substrate 1. The plurality of inorganic LED chips 2 are connected respectively to the control circuits 4, and the control circuits 4 are configured to drive the plurality of inorganic LED chips 2 to emit light respectively. The photoluminescent layer 5 is between the transparent cover plate 3 and the plurality of inorganic LED chips 2, and the photoluminescent layer 5 is configured to excite colored light under irradiation of the light emitted by the inorganic LED chips 2. FIG. 2 is a schematic view showing a structure of a substrate of the LED display module according to the embodiment of the present disclosure. In combination with FIG. 2, the plurality of inorganic LED chips 2 are arranged in array on one side face of the substrate 1.

In embodiments of the present disclosure, due to provision of the photoluminescent layer on the inorganic LED chips, the photoluminescent layer excites colored light under irradiation of the light emitted by the inorganic LED chips, which eliminates the problem that the display module including an organic material that excites colored light has a short life due to short life of the organic material, and thus prolongs service life of the display module. Meanwhile, since inorganic LED chips are used to emit light, the current needs not to be increased to enhance brightness of the blue light, which reduces power consumption of the display module.

In an implementation of the present embodiment, each inorganic LED chip 2 comprises a N-type gallium nitride layer 21 formed on one side face of the substrate 1, a heavily doped gallium nitride layer 23 formed on a partial region of the N-type gallium nitride layer 21, and a P-type gallium nitride layer 22 formed on the heavily doped gallium nitride layer 23; and, N-type a cathode 25 is provided with on the N-type gallium nitride layer 21 and P-type an anode is provided on the P-type gallium nitride layer 22. Since the inorganic LED chip 2 of gallium nitride material involves a mature manufacturing process, the inorganic LED chip 2 made of gallium nitride material is selected to emit light to excite the photoluminescent layer 5, which reduces difficulty in process and manufacturing cost. Meanwhile, since the inorganic LED chip 2 made of gallium nitride material has a blue light effect greater in five times than that of the OLED, use of the inorganic LED chip 2 made of gallium nitride material may further reduce power consumption.

In one example, the substrate 1 preferably is a sapphire substrate. Sapphire has good mechanical and optical properties. Meanwhile, since the inorganic LED chip 2, which uses the sapphire as the substrate 1, may be manufactured by a mature manufacturing process, manufacturing cost is low.

It should be noted that, in order for convenient description, only six inorganic LED chips 2 are shown in FIG. 2. In practical application, the number of the inorganic LED chips 2 may be set in accordance with practical requirement, and it is not limited in the present disclosure.

Moreover, a material for a cathode 25 of the inorganic LED chip 2 may be copper-platinum-gold ternary alloy, which owns good ductility and is suitable for manufacture of micro-scaled electrode, and which also owns good electrical and thermal conductivity, reducing heat generation of the LED chip 2 and improving heat-sinking capability.

In one example, the inorganic LED chip 2 may be connected in a cathode-sharing manner. Specifically, cathodes of a plurality of inorganic LED chips 2 arranged along one gate line 42 are connected with one another. Adoption of the connection in the cathode-sharing manner may simplify arrangement of the wires between the inorganic LED chips 2 and a power source.

Optionally, the photoluminescent layer 5 and the control circuits 4 are formed at the same side face of the transparent cover plate 3. Formations of the photoluminescent layer 5 and the control circuits 4 at the transparent cover plate 3 are not interrupted with the inorganic LED chips 2 in production and are simple in process.

In another embodiment of the present disclosure, the photoluminescent layer 5 and the control circuits 4 may also be formed at one side face of the substrate 1, or else, one is formed one side face of the substrate 1 and the other is formed one side face of the transparent cover plate 3.

According to embodiments of the present disclosure, the transparent cover plate 3 includes but is not limited to a glass cover plate, a plastic cover plate, a sapphire cover plate or the like.

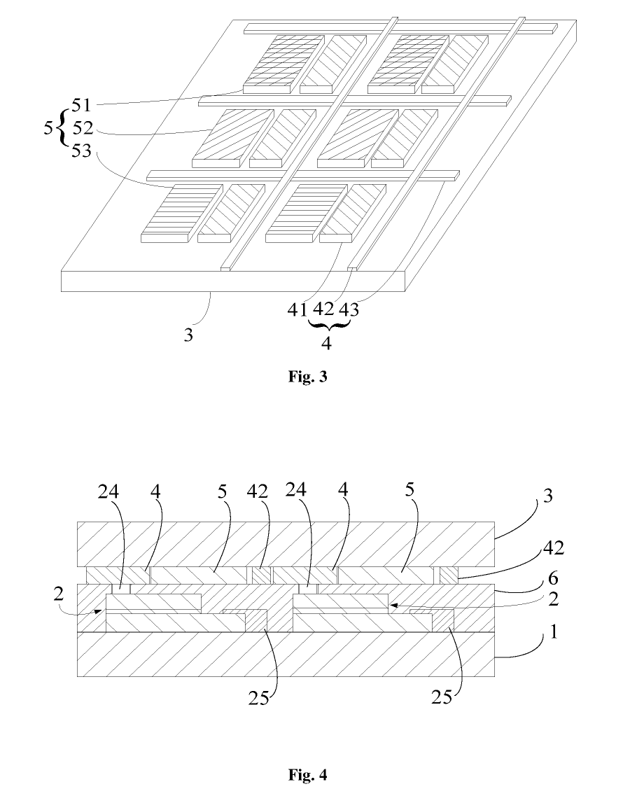

FIG. 3 is a schematic view showing a structure of a transparent cover plate of the LED display module according to the embodiment of the present disclosure. Referring to FIG. 3, the control circuit 4 comprise a gate line 42 and a data line 43 crossing the gate line 42, and a plurality of the gate lines 42 and a plurality of the data lines 43 are crossed with one another to form a plurality of meshes, a pixel driving circuit 41 is provided in each of the meshes and is connected with the gate line 42 and the data line 43, respectively, and the pixel driving circuits 41 are connected in a one-to-one correspondence with the inorganic LED chips 2. Through the pixel driving circuits 41, the gate lines 42 and the data lines 43 control the inorganic LED chips 2 to emit light.

In one example, each pixel driving circuit 41 at least comprises a thin film transistor, of which a gate is connected with the gate line 42, a source is gate is connected with the data line 43, and a drain is connected with the anode of the inorganic LED chip 2.

It should be noted that, the pixel driving circuit 41 may also be selected from pixel driving circuits of various currently known AMOLEDs. The pixel driving circuit 41 may include a plurality of thin film transistors and a plurality of capacitors, and the inorganic LED chip 2 is driven to emit light under combined action of the plurality of thin film transistors and the plurality of capacitors. Meanwhile, the pixel driving circuit 41 may have a circuit compensation function, such as voltage compensation.

Moreover, the photoluminescent layer 5 comprises a plurality of photoluminescent units, and each photoluminescent unit corresponds to three inorganic LED chips 2 arranged side by side along the gate line 42. Three inorganic LED chips 2 arranged side by side along the gate line 42 are provided to correspond to one photoluminescent unit, such that three inorganic LED chips 2 may together excite one photoluminescent unit to emit light, and brightness of the three inorganic LED chips 2 may be adjusted to control the one photoluminescent unit to emit light.

In the embodiment shown in FIG. 3, the photoluminescent unit comprises a first sub-photoluminescent unit 51, a second sub-photoluminescent unit and a third sub-photoluminescent unit 53 provided alternately, the first sub-photoluminescent unit 51 excites a red light under irradiation of the light emitted by the inorganic LED chip 2, the second sub-photoluminescent unit 52 excites a green light under irradiation of the light emitted by the inorganic LED chip 2, and the third sub-photoluminescent unit 53 excites a blue light under irradiation of the light emitted by the inorganic LED chip 2, so that red, green and blue three colored lights can be obtained. In this embodiment, one pixel unit of the LED display module comprises one photoluminescent unit and three inorganic LED chips 2 provided corresponding to the one photoluminescent unit and pixel driving circuits 41 configured to control the three inorganic LED chips 2 to emit light. By controlling the three inorganic LED chips 2 in one pixel unit to emit light, the one pixel unit can emit lights of different colors, so that the LED display module may display different colors.

It should be noted that, the order between the first sub-photoluminescent unit 51, the second sub-photoluminescent unit 52 and the third sub-photoluminescent unit 53 is not limited to the order shown in FIG. 3.

In the embodiment, the third sub-photoluminescent unit 53 excites blue light having a wavelength of 450 nm (nanometer)˜460 nm under irradiation of the light emitted by the inorganic LED chip 2. The blue light emitted by the inorganic LED chip 2 has a wavelength of about 435 nm, which is harmful to human's eyes, accordingly, the blue light having a wavelength of about 435 nm is converted by the third sub-photoluminescent unit 53 into a blue light having a wavelength of 450 nm˜460 nm, thereby reducing harm of the blue light emitted by the inorganic LED chip 2 on human's eyes.

In another embodiment of the present disclosure, the photoluminescent unit may comprise only the abovementioned first sub-photoluminescent unit 51 and the abovementioned second sub-photoluminescent unit 52, and include no third sub-photoluminescent unit 53. The blue light emitted by the inorganic LED chip is adopted directly. The first sub-photoluminescent unit 51 excites a red light under irradiation of the light emitted by the inorganic LED chip 2, and the second sub-photoluminescent unit 52 excites a green light under irradiation of the light emitted by the inorganic LED chip 2, so that red light and green light can be obtained. Meanwhile, the inorganic LED chip emits the blue light. As a result, red, green and blue three colored lights can be obtained. In this embodiment, coverage area of the photoluminescent layer 5 can be reduced and the cost is reduced.

It should be noted that, the photoluminescent layer 5 may be a quantum dot color filter film. Quantum dot color filter film is a thin film material having quantum dots in its surface, and the quantum dot usually has a spherical shape or spherical-like shape and is made of semiconductor material and is a nano particle having a diameter of 2 nm˜20 nm. Its specific manufacturing process is known as prior art and is omitted herein for the sake of brevity.

FIG. 4 is a schematic view showing a structure of another LED display module according to an embodiment of the present disclosure. Referring to FIG. 4, the LED display module further comprises a passivation layer 6 between the control circuits 4 and the inorganic LED chips 2, the passivation layer 6 is provided with a through hole thereon, and an anode of the inorganic LED chip 2 is connected to the control circuit 4 through a conductor 24 provided in the through hole. Provision of the passivation layer is advantage, as in this embodiment, the passivation layer has a separation function such as to avoid occurrence of short circuit in the inorganic LED chip 2. Moreover, contrary to the point of view of those skilled in the art to reduce thickness of the whole device, provision of the passivation layer 6 can increase critical angle of a total reflection between the light emitted by the inorganic LED chip 2 and the air, and reduce amount of the light reflected into the inorganic LED chip 2, and thus increase the brightness.

Optionally, the passivation layer 6 may be made of silicon dioxide or silicon nitride.

In one example, the conductor 24 can be made of ITO (tin indium oxide). Use of the ITO electrode can allow the electrode material to absorb reduced light emitted by the inorganic LED chip 2, so as to increase the brightness.

Optionally, the LED display module may further comprise a light reflecting layer provided at one side face of the substrate away from the inorganic LED chip 2. The reflecting layer reflects some of the light emitted by the inorganic LED chip 2 to the side face as light outgoing side, thereby increasing the brightness of the inorganic LED chip 2.

In one example, the light reflecting layer can be made of silver metal that has good light reflective property. It can reflect most of the light irradiated on the silver metal toward the light outgoing side, thereby increasing the brightness of the inorganic LED chip 2.

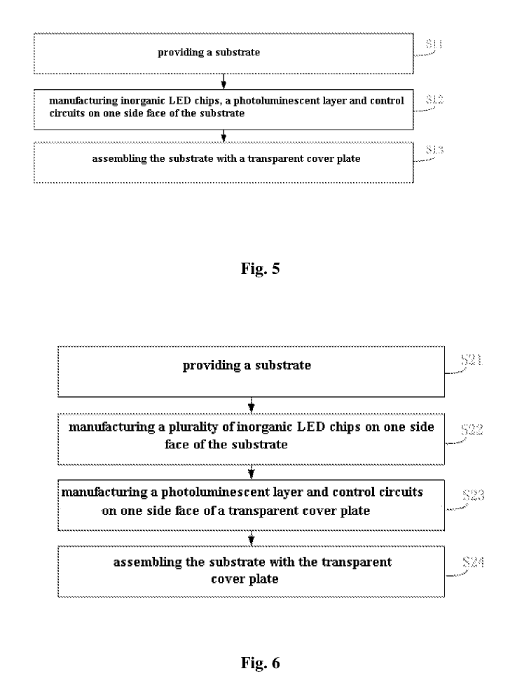

FIG. 5 is a flow diagram showing a method of manufacturing a LED display module according to an embodiment of the present disclosure. The method is used for manufacturing any one of the abovementioned LED display modules. Referring to FIG. 5, the method comprises steps of:

S11: providing a substrate;

S12: manufacturing inorganic LED chips, a photoluminescent layer and control circuits on one side face of the substrate; wherein, the plurality of inorganic LED chips are arranged in array on one side face of the substrate and the plurality of inorganic LED chips are connected respectively to the control circuits, the control circuits are configured to drive the plurality of inorganic LED chips to emit light; in a direction perpendicular to the substrate, the photoluminescent layer is located above the inorganic LED chips and is configured to excite colored light under irradiation of the light emitted by the inorganic LED chips;

S13: assembling the substrate with a transparent cover plate.

In embodiments of the present disclosure, due to provision of the photoluminescent layer on the inorganic LED chips, the photoluminescent layer excites colored light under irradiation of the light emitted by the inorganic LED chips, which eliminates the problem that the display module has a short life due to short life of the organic material that excites colored light, and thus prolongs service life of the display module. Meanwhile, since inorganic LED chips are used to emit light, the current needs not to be increased to enhance brightness of the blue light, which reduces power consumption of the display module.

In practical production, step S12 can include: firstly the inorganic LED chips are manufactured on one side face of the substrate, then the passivation layer is manufactured on the inorganic LED chips, after that, the control circuits are manufactured on the passivation layer, and finally, the passivation layer is manufactured on the control circuits.

It should be noted that, the passivation layer is provided with through holes therein, and anodes of the inorganic LED chips are connected to the control circuit through conductors provided in the through holes.

In one example, the passivation layer may be made of silicon dioxide or silicon nitride, and the conductors may be made of ITO.

In addition, a light reflecting layer can be further manufactured on one side face of the substrate away from the inorganic LED chips.

In one example, the light reflecting layer may be made of metal silver.

FIG. 6 is a flow diagram showing another method of manufacturing a LED display module according to an embodiment of the present disclosure. The method is used for manufacturing any one of the abovementioned LED display modules. Referring to FIG. 6, the method comprises steps of:

S21: providing a substrate, wherein the substrate may be a sapphire substrate;

S22: manufacturing a plurality of inorganic LED chips on one side face of the substrate, the plurality of inorganic LED chips being arranged in array on the one side face of the substrate;

S23: manufacturing a photoluminescent layer and control circuits on one side face of a transparent cover plate, wherein, the control circuits are configured to drive the plurality of inorganic LED chips to emit light, and the photoluminescent layer is configured to excite colored light under irradiation of the light emitted by the inorganic LED chips;

S24: assembling the substrate with the transparent cover plate such that the plurality of inorganic LED chips are connected respectively with the control circuits.

In embodiments of the present disclosure, due to provision of the photoluminescent layer on the inorganic LED chips, the photoluminescent layer excites colored light under irradiation of the light emitted by the inorganic LED chips, which eliminates the problem that the display module has a short life due to short life of the organic material that excites colored light, and thus prolongs service life of the display module. Meanwhile, since inorganic LED chips are used to emit light, the current needs not to be increased to enhance brightness of the blue light, which reduces power consumption of the display module.

In practical production, step S22 may include: firstly the inorganic LED chips are manufactured on one side face of the substrate, and then the passivation layer is manufactured on the inorganic LED chips.

It should be noted that, the passivation layer is provided with through holes thereon, and anodes of the inorganic LED chips are connected to the control circuit through conductors provided in the through holes.

In one example, the passivation layer may be made of silicon dioxide or silicon nitride, and the conductors may be made of ITO.

When it is implemented, step S23 may include: firstly the control circuits are manufactured on the transparent cover plate, and then the photoluminescent layer is manufactured.

In addition, a light reflecting layer can be further manufactured on one side face of the substrate away from the inorganic LED chips.

In one example, the light reflecting layer may be made of metal silver.

According to embodiments of the present disclosure, there further provides a LED display device comprising any one of the abovementioned LED display modules.

In embodiments of the present disclosure, due to provision of the photoluminescent layer on the inorganic LED chips, the photoluminescent layer excites colored light under irradiation of the light emitted by the inorganic LED chips, which eliminates the problem that the display module has a short life due to short life of the organic material that excites colored light, and thus prolongs service life of the display module. Meanwhile, since inorganic LED chips are used to emit light, the current needs not to be increased to enhance brightness of the blue light, which reduces power consumption of the display module.

The LED display device can be any of products or components having a display function, including liquid crystal panel, electronic paper, LED panel, mobile phone, tablet computer, TV, displayer, notebook computer, digital photo frame, navigator and the likes.

The above merely are embodiments of the present disclosure, but the scope of the present disclosure is not limited to this. Changes, equivalent replacements and modifications on these embodiments made without departing from the principles and spirit of the present disclosure fall into the scope of the present disclosure.

1. A light-emitting diode (LED) display module, comprising: a substrate, a plurality of inorganic LED chips, control circuits, a photoluminescent layer and a transparent cover plate; wherein,
the transparent cover plate and the substrate are provided opposite to each other;
the control circuits, the photoluminescent layer and the plurality of inorganic LED chips are between the transparent cover plate and the substrate;
the plurality of inorganic LED chips are arranged in array on one side face of the substrate and the plurality of inorganic LED chips are connected respectively to the control circuits such that the control circuits can drive the plurality of inorganic LED chips to emit light; and
the photoluminescent layer is between the transparent cover plate and the plurality of inorganic LED chips such that the photoluminescent layer excites colored light under irradiation of the light emitted by the inorganic LED chips.

2. The LED display module of claim 1, wherein, the photoluminescent layer and the control circuits are formed at the same side face of the transparent cover plate.

3. The LED display module of claim 1, wherein, the control circuits comprise a gate line and a data line crossing the gate line, and a plurality of the gate lines and a plurality of the data lines are crossed with one another to form a plurality of meshes, a pixel driving circuit is provided in each of the meshes and is connected with the gate line and the data line, respectively, and the pixel driving circuits are connected in a one-to-one correspondence with the inorganic LED chips.

4. The LED display module of claim 3, wherein, the photoluminescent layer comprises a plurality of photoluminescent units, each photoluminescent unit corresponding to three of the inorganic LED chips provided side by side along the gate line.

5. The LED display module of claim 4, wherein, each photoluminescent unit comprises a first sub-photoluminescent unit and a second sub-photoluminescent unit provided alternately, the first sub-photoluminescent unit excites a red light under irradiation of the light emitted by the inorganic LED chips, the second sub-photoluminescent unit excites a green light under irradiation of the light emitted by the inorganic LED chips, and the light emitted by the inorganic LED chips is a blue light.

6. The LED display module of claim 5, wherein, each photoluminescent unit further comprises a third sub-photoluminescent unit, and the third sub-photoluminescent unit excites a blue light under irradiation of the light emitted by the inorganic LED chips.

7. The LED display module of claim 6, wherein, the third sub-photoluminescent unit excites a blue light, under irradiation of the light emitted by the inorganic LED chips, having a wavelength of 450 nm˜460 nm.

8. The LED display module of claim 1, wherein, the photoluminescent layer is a quantum dot color filter film.

9. The LED display module of claim 1, wherein, the LED display module further comprises a passivation layer between the control circuits and the inorganic LED chips, the passivation layer is provided with a through hole therein, and an anode of the inorganic LED chip is connected to the control circuits through a conductor provided in the through hole.

10. The LED display module of claim 8, wherein, the conductor is made of tin indium oxide.

11. The LED display module of claim 1, wherein, a material for a cathode of the inorganic LED chip comprises a copper-platinum-gold ternary alloy.

12. The LED display module of claim 1, wherein, the inorganic LED chip comprises a N-type gallium nitride layer formed on one side face of the substrate, a heavily doped gallium nitride layer formed on a partial region of the N-type gallium nitride layer, and a P-type gallium nitride layer formed on the heavily doped gallium nitride layer; and, the N-type gallium nitride layer is provided with the cathode and the P-type gallium nitride layer is provided with the anode.

13. The LED display module of claim 1, wherein, the substrate comprises a sapphire substrate.

14. The LED display module of claim 1, wherein, the LED display module further comprises a light reflecting layer provided at one side face of the substrate away from the inorganic LED chips.

15. An LED display device, wherein, the display device comprises the LED display module of claim 1.

16. A method of manufacturing an LED display module, wherein, the method comprises:
providing a substrate;
manufacturing a plurality of inorganic LED chips, a photoluminescent layer and control circuits on one side face of the substrate, wherein,
the plurality of inorganic LED chips are arranged in array on the side face of the substrate and the plurality of inorganic LED chips are connected respectively to the control circuits,
the control circuits are configured to drive the plurality of inorganic LED chips to emit light; in a direction perpendicular to the substrate, and
the photoluminescent layer is located above the inorganic LED chips and is configured to excite colored light under irradiation of the light emitted by the inorganic LED chips; and
assembling the substrate with a transparent cover plate.

17. A method of manufacturing an LED display module, wherein, the method comprises:
providing a substrate;
manufacturing a plurality of inorganic LED chips on one side face of the substrate, the plurality of inorganic LED chips being arranged in array on the one side face of the substrate;
manufacturing a photoluminescent layer and control circuits on one side face of a transparent cover plate, wherein, the control circuits are configured to drive the plurality of inorganic LED chips to emit light, and the photoluminescent layer is configured to excite colored light under irradiation of the light emitted by the inorganic LED chips;
assembling the substrate with the transparent cover plate such that the plurality of inorganic LED chips are connected respectively with the control circuits

18. The LED display module of claim 2, wherein, the inorganic LED chip comprises a N-type gallium nitride layer formed on one side face of the substrate, a heavily doped gallium nitride layer formed on a partial region of the N-type gallium nitride layer, and a P-type gallium nitride layer formed on the heavily doped gallium nitride layer; and, the N-type gallium nitride layer is provided with the cathode and the P-type gallium nitride layer is provided with the anode.

19. The LED display module of claim 3, wherein, the inorganic LED chip comprises a N-type gallium nitride layer formed on one side face of the substrate, a heavily doped gallium nitride layer formed on a partial region of the N-type gallium nitride layer, and a P-type gallium nitride layer formed on the heavily doped gallium nitride layer; and, the N-type gallium nitride layer is provided with the cathode and the P-type gallium nitride layer is provided with the anode.
